(19) United States
(12) Patent Application Publication
(10) Pub. No.: US 2024/0112944 A1
(43) Pub. Date: Apr. 4, 2024

(54) Process for Wafer Bonding

(71) Applicant: IMEC VZW, Leuven (BE)

(72) Inventors: Jakob Visker, Herent (BE); Lan Peng, Leuven (BE); Serge Vanhaelemeersch, Heverlee (BE); Aurelie Humbert, Schaarbeek (BE); Chi Dang Thi Thuy, Heverlee (BE); Evert Visker, Leuven (BE)

(21) Appl. No.: 18/474,803

(22) Filed: Sep. 26, 2023

(30) Foreign Application Priority Data
Oct. 4, 2022 (EP) 22199670.5

(51) Int. Cl. H01L 21/683; B32B 43/00; H01L 21/30

(52) U.S. Cl. CPC H01L 21/6836; B32B 43/006; H01L 21/30

(57) ABSTRACT

The present disclosure relates to a temporary wafer bonding process including the steps of: providing a wafer for back processing by laminating a plain protective film on a front surface of the wafer; providing a rigid carrier; bonding the rigid carrier to the plain protective film by the intermediate of a bonding material layer; processing a back surface of the wafer; and separating the rigid carrier and the plain protective film from the wafer.

### CROSS-REFERENCE

The present application claims priority based on EP application no. 22199670.5, filed on Oct. 4, 2022, which is incorporated by reference in its entirety.

### TECHNICAL FIELD

The present disclosure is generally related to a process for wafer bonding in semiconductor processing and more specifically to a process for temporary wafer bonding for back processing.

### Background of the Present Disclosure

Temporary wafer bonding refers to a process where a wafer is temporarily bonded to a rigid carrier with “temporary bonding material” and, later on, the rigid carrier is separated or de-bonded from the wafer. Temporary wafer bonding is an important step of the manufacturing of semiconductor devices. An adhesive temporary bonding material is often used for the bonding process.

A known technique for temporary wafer bonding using an adhesive temporary bonding material is explained in document “Development of Micrometer-Thick Bonding Material for Wafer-On-Wafer (WOW) Applications” by N. Araki et al., 2018 13th International Microsystems, Packaging, Assembly and Circuits Technology Conference (IMPACT), 2018, pp. 214-217.

Using an adhesive temporary bonding material leaves glue residues on the wafer after debonding. To remove the residues, rinsing with an aggressive chemical is generally required. However, the rinsing chemical can damage the front surface of the wafer, especially if it is thin and/or structured. Therefore, there is a need in the art to overcome at least partly this issue.

### SUMMARY OF THE PRESENT DISCLOSURE

The present disclosure is set out in the appended set of claims.

It is an objective of the present disclosure to at least partly overcome the limitations of the prior art. In particular, it is an object to provide a process for efficiently preventing glue residue on the wafer as a result of a temporary wafer bonding process.

According to the present disclosure, a process for temporary wafer bonding comprises:

providing a wafer for back processing by
a. a.1 laminating a plain protective film on a front surface of the wafer.

providing a rigid carrier.

bonding the rigid carrier to the plain protective film by the intermediate of a bonding material layer.

processing a back surface of the wafer.

separating the rigid carrier and the plain protective film from the wafer.

Benefits provided by the embodiments of the present disclosure include preventing partly or completely the presence of the residue from the bonding material layer, such as glue residue, on the front surface of the wafer after the rigid carrier and the plain protective film are completely separated from the wafer. It also protects the structures on the front surface from the mechanical stress induced by the bonding process. Therefore, the device performance and yield would not affected by the temporary wafer bonding. Conventional temporary bonding processes coat the bonding material on the rigid carrier by, for example, spin coating. In such processes, the wafer is bonded to the rigid carrier where the bonding material directly contacts the front surface of the wafer. In the present disclosure, the bonding material can be coated on the rigid carrier and the wafer can be bonded to the rigid carrier where the bonding material contacts the plain protective film. At least part of the bonding material can be alternatively coated directly on the plain protective film. Therefore, the bonding material has no contact with the front surface of the wafer, especially when the bonding material comprises a glue layer. It is a benefit of embodiments of the present disclosure that they are compatible with standard CMOS materials and applicable for a wide range of devices.

According to an example embodiment, the process is for temporary wafer bonding in fabrication of Micro-Electro-Mechanical Systems (MEMS).

According to an example embodiment, the step (e) of separating the rigid carrier and the plain protective film from the wafer comprises:
e.1. separating the rigid carrier from the plain protective film; followed by
e.2. removing the plain protective film from the front surface of the wafer.

It is a benefit a benefit of this embodiment that it consumes limited amount of chemicals to remove the plain protective film. This step order gives an easy chemical access to the plain protective film.

According to an example embodiment, the step e of separating the rigid carrier and the plain protective film from the wafer comprises a wet etching step before the step (e.2) of removing the plain protective film from the front surface of the wafer. It is a benefit a benefit because the front surface of the wafer is protected during the wet etching step.

According to an example embodiment, the step e of separating the rigid carrier and the plain protective film from the wafer comprises a step of wet etching the bonding material layer after step (e.1) of separating the rigid carrier from the plain protective film and before the step (e.2) of removing the plain protective film from the front surface of the wafer. It is a benefit because the front surface of the wafer is protected during the wet etching of at least part of the bonding material layer.

According to an example embodiment, the step (e) of separating the rigid carrier and the plain protective film from the wafer comprises a step of wet etching glue residues on the plain protective film after step (e.1) of separating the rigid carrier from the plain protective film. This is beneficial because the front surface of the wafer can be protected during the wet etching of the glue residues from the bonding material layer. As an added benefit, the complete removal of the bonding material layer allows controllable removal of the plain protective film from the front surface of the wafer.

According to an example embodiment, the step (e) of separating the rigid carrier and the plain protective film from the wafer comprises wet etching the plain protective film. This is beneficial as the laminated plain protective film can be removed with controlled amount of chemicals so that the exposure time of the front surface of the wafer to the chemicals is limited. The front surface of the wafer has a limited contact time with etching chemicals. This prevents damages to fragile structures exposed to the etching chemicals. The potential damage of the front surface of the wafer from the chemicals is also limited.

According to an example embodiment, the step (d) of processing a back surface of the wafer comprises a heating step of the back surface above 150° C. According to an example embodiment, the step (d) of processing a back surface of the wafer comprises a heating step of the back surface above 300° C. It is beneficial that the process can be compatible with complex back processing steps. In the processes comprising a heating step, they further prevent glue contamination from glue bubbling at high temperatures.

According to an example embodiment, the wafer is a semiconductor substrate, optionally comprising CMOS circuitry. This is beneficial in that they are compatible with CMOS fabrication steps performed on the wafer before, during, or after the process.

According to an example embodiment, the rigid carrier is transparent.

Beneficially, using a rigid carrier that it provides mechanical stability during the bonding process. It protects the wafer from mechanical stress induced by the bonding process and further prevents or reduces cracks on or in the wafer during the process. The rigid carrier provides physical support during back processing. As an added benefit, using a transparent rigid carrier can enable visibility of optical alignment marks, such as optical alignment marks for hardmask alignment, through the transparent carrier.

According to an example embodiment, the rigid carrier is a glass carrier. This can be a benefit as a glass carrier is compatible with CMOS fabrication processes.

According to an example embodiment, the front surface of the wafer comprises a cavity, optionally extending to the back surface, before the step (a.1) of laminating a plain protective film on a front surface of the wafer. As a benefit, they are compatible with a complex topography of the front surface of the wafer, such as protrusions and/or cavities. Contrary to a conventional spin-on coating of an adhesive bonding material directly on a wafer, or other analog deposition methods, especially when applied on a complex topography with cavities, the laminated plain protective film used is mostly attached to the front surface of the wafer and does not substantively flow into device features such as cavities.

According to an example embodiment, the cavity has an aspect ratio of at least 1. According to an example embodiment, the cavity has an aspect ratio of at least 2. The process can provide a benefit in that it prevents glue contamination inside any cavity at the front surface of the wafer, especially deep cavities.

According to an example embodiment, the wafer in the step (a) of providing a wafer (1) for back processing comprises a stack of layers.

According to an example embodiment, the wafer in the step (a) of providing a wafer (1) for back processing comprises a stack of layers, wherein at least one layer is formed by wafer bonding. More specifically, the at least one layer is formed by (sub-)wafer-to-(sub-)wafer bonding. The process can be beneficial in that it is compatible with complex processing steps prior to bonding. In some embodiments of the present disclosure, it can be a benefit where a stack of layers can be bonded, thereby forming a wafer, prior to the temporary bonding process.

According to an example embodiment, the plain protective film comprises a polymer, typically having a glass transition temperature below 100° C. The properties of the plain protective film can beneficially allow cost-effective lamination.

According to an example embodiment, the plain protective film either is glue-free or comprises a glue layer of thickness thinner than 5 nm on the surface of the plain protective film that will contact the front surface of the wafer during step (a.1) of laminating a plain protective film on a front surface of the wafer. It can be a benefit where the plain protective film is not glued to the front surface of the wafer and instead is attached to the front surface by lamination. Therefore, no glue residue is left on the front surface when using a glue-free plain protective film. Even when the plain protective film comprises a glue layer of thickness thinner than 5 nm, the glue residues left on the front surface of the wafer are very limited.

According to an example embodiment, the bonding material layer comprises a photosensitive material. It can be beneficial that the bonding material layer can be removed from the plain protective film by exposing the bonding material layer to light.

According to an example embodiment, the step (e) of separating the rigid carrier and the plain protective film from the wafer comprises a step of exposing the bonding material layer to UV light. As a benefit, the process can be compatible with conventional debonding methods.

According to an example embodiment, the step (a.1) of laminating a plain protective film on a front surface of a wafer is performed at a temperature above 85° C. and a pressure above 103 kPa. Beneficially, the plain protective film can be efficiently laminated on the front surface of the wafer.

### BRIEF DESCRIPTION OF THE DRAWINGS

FIG. 1 is a flowchart showing the steps of example processes according to the present disclosure.

FIGS. 2a to 2e show an example schematic illustration of a series of vertical cross sections through intermediate structures obtained during steps of the process flowchart of FIG. 1. In FIG. 2a, wafer 1 is provided. In FIG. 2b, the plain protective film 2 is laminated on the front surface 1a of the wafer 1. In FIG. 2c, a layer of temporary bonding material (not shown in the figure) is applied on the plain protective film 2. A rigid carrier 3 is bonded to the plain protective film 2 by the intermediate of the adhesive temporary bonding material layer. In FIG. 2d, the wafer 1 is flipped over so that the back surface 1b can be easily processed. In FIG. 2e, the wafer 1 is flipped over again so that the rigid carrier 3 and the plain protective film can be more easily removed from the front surface 1a of the wafer 1.

FIGS. 3a to 3c show an example schematic illustration of a vertical cross sections through different exemplary cavities in the wafer. FIG. 3a shows that the front surface 1a of the wafer 1 comprises a cavity. FIG. 3b shows that the cavity extends vertically from the front surface 1a to the back surface 1b of the wafer 1. FIG. 3c shows that the cavity extends vertically from the front surface 1a of the wafer 1 and fluidically connects with a cavity extending horizontally within the wafer 1.

FIGS. 4a to 4e show a second example schematic illustration of a series of vertical cross sections through intermediate structures obtained during steps of the process flowchart of FIG. 1. FIG. 4a shows cavity 41a formed on the layer 41. FIG. 4b shows plain protective film 2 laminated on the front surface 1a of the wafer 1. FIG. 4c shows a rigid carrier 3 bonded to the plain protective film 2 by the intermediate of the adhesive temporary bonding material layer. FIG. 4d shows the wafer 1 flipped over so that the back surface 1b can be easily processed. FIG. 4e shows the wafer 1 flipped over again so that the rigid carrier 3 and the plain protective film can be more easily removed from the front surface 1a of the wafer 1.

FIGS. 5a to 5e show a third example schematic illustration of a series of vertical cross sections through intermediate structures obtained during steps of the process flowchart of FIG. 1. FIG. 5a shows wafer 1 comprising a stack of semiconductor layers 51, 52 wherein at least one semiconductor layer comprises CMOS circuitry embedded therein. FIG. 5b shows protective film 2 laminated on the front surface 1a of the wafer 1. FIG. 5c shows a rigid carrier 3 bonded to the plain protective film 2 by the intermediate of the adhesive temporary bonding material layer. FIG. 5d shows the wafer 1 is flipped over so that back surface 1b can be easily processed. FIG. 5e shows the wafer 1 is flipped over again so that the rigid carrier 3 and the plain protective film can be more easily removed from the front surface 1a of the wafer 1.

FIGS. 6a to 6b show pictures of the wafer after conventional temporary bonding processes. FIG. 6a shows residues of the bonding material on the wafer. FIG. 6b shows cracks on the front surface of the wafer during conventional processing.

FIG. 6c shows an example picture of a wafer after a process according to the present disclosure.

### DETAILED DESCRIPTION OF THE DISCLOSURE

The disclosure will be further elucidated by means of the following description and the appended figures. Various exemplary embodiments are described herein with reference to the following figures, wherein like numeral denotes like entities. The figures described are schematic and are non-limiting. Further, any reference signs in the claims shall not be construed as limiting the scope of the present disclosure. Still further, in the different figures, the same reference signs refer to the same or analogous elements.

The terms “over” and “above” are used for position indication of layers and not necessarily for describing a direct contact of the layers. It is to be understood that the terms so used are interchangeable under appropriate circumstances. The term “on” is used for position indication of layers and describing a direct contact of the layers.

The term “comprising”, used in the claims, should not be interpreted as being restricted to the means listed thereafter; it does not exclude other elements or steps. It is thus to be interpreted as specifying the presence of the stated features, integers, steps, or components as referred to, but does not preclude the presence or addition of one or more other features, integers, steps or components, or groups thereof. The term “comprising” therefore covers the situation where only the stated features are present (and can therefore always be replaced by “consisting of” in order to restrict the scope to said stated features) and the situation where these features and one or more other features are present. The scope of the expression “a device comprising means A and B” should therefore not be interpreted as being limited to devices consisting only of components A and B. It may mean that the only relevant components of the device are A and B.

The term “a” shall be interpreted as a function word before a mass noun to denote a particular type or instance. It should not be interpreted as a function word before a singular noun referring one object.

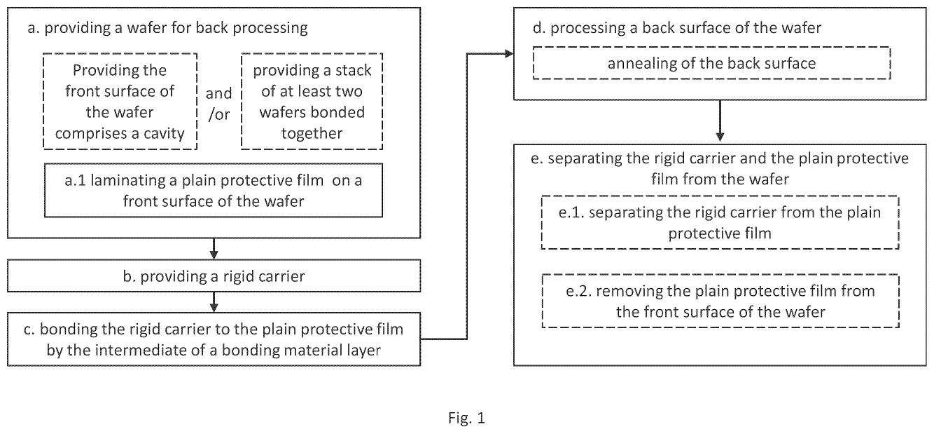

As shown in FIG. 1, the present disclosure relates to a process for temporary wafer bonding, comprising steps of

a. providing a wafer for back processing by
a.1 laminating a plain protective film on a front surface of the wafer;
b. providing a rigid carrier;
c. bonding the rigid carrier to the plain protective film by the intermediate of a bonding material layer;
d. processing a back surface of the wafer;
e. separating the rigid carrier and the plain protective film from the wafer.

In the field of semiconductor manufacturing, the term “wafer” can take two meanings. In a first definition, a wafer is a slice of semiconductor (such as silicon or germanium) used as a base for an electronic component or circuit. In that definition, a wafer is a one-piece semiconductor structure. The term wafer is, however, also frequently used in the semiconductor manufacturing industry to group together wafers according to the first definition as well as semiconductor structures comprising a wafer according to the first definition. For instance, such semiconductor structures may comprise the following elements in addition to the wafer according to the first definition:
one or more further wafers according to the first definition (i.e., sub-wafers), and/or
one or more layers (e.g., semiconductor layers, bonding material layers, bonded layers, . . . ), and/or
electronic circuitry.

In the present disclosure, this second definition is used and wafers according to the first definition will generally be referred to as sub-wafers.

In embodiments, the wafer can comprise a silicon or germanium substrate. It can further comprise one or more layers of semiconductor materials, such as one or more silicon layers (e.g., sub-wafers) or one or more germanium layers (e.g., sub-wafers). In typical examples, the wafer may comprise a silicon substrate and one or more additional silicon layers. In another typical examples, the wafer may comprise a germanium substrate and one or more additional germanium layers. For instance, the wafer may comprise a semiconductor substrate and the one or more layers of semiconductor materials may comprise a further semiconductor substrate. In such embodiments, the wafer may comprise two or more semiconductor substrates bonded together, e.g., by wafer bonding.

Wafer bonding refers to a thermo-compression bonding process by which a wafer and a substrate of any material adhere to each other. The process involves the application of a gluing layer. Temporary wafer bonding refers to a process where a wafer is temporarily adhered or bonded to a rigid carrier with a bonding material and later on the rigid carrier is separated or de-bonded from the wafer. Bonding material refers to a group of polymeric bonding materials which forms at least an adhesive layer between the wafer and the substrate.

The term “front surface” and “back surface” are used as references for certain surfaces of the wafer. It is to be understood that the “front surface” can appear as a bottom surface in figures under appropriate circumstances, for example when the wafer is turned around. And “back surface” is the surface of the wafer at the opposite from the “front surface”. The “front surface” and the “back surface” are typically substantially in parallel planes.

The term “laminating” or “lamination” refers to a process of pressing a layer of dry film on the wafer by pressing and rotating at least one roller on the dry film. The lamination step is often followed by a baking step at a temperature, e.g., above 30° C.

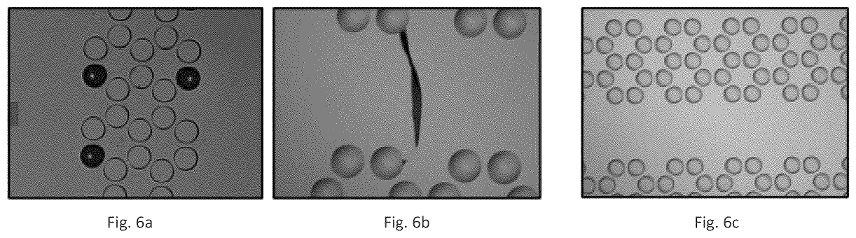

As shown in FIG. 6c, the structure and yield of the wafer after step (e) of separating the rigid carrier and the plain protective film from the wafer are not affected by the temporary wafer bonding. The process in the present disclosure avoids residues of the bonding material on the wafer, as shown in FIG. 6a, after debonding. The process in the present disclosure can avoid cracks, as shown in FIG. 6b, on the front surface of the wafer during the process.

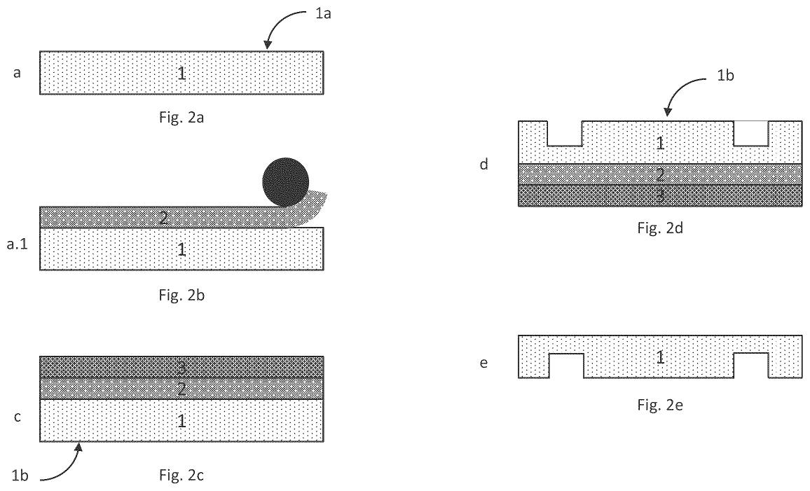

We now refer to FIG. 2. According to an example embodiment, the step (a.1) of laminating a plain protective film 2 on a front surface 1a of a wafer 1 is performed at a temperature above 85° C. and a pressure above 103 kPa. According to an example embodiment, the lamination temperature ranges from 85 to 110° C., for example at 95° C. According to an example embodiment, the step (a.1) of laminating a plain protective film 2 on a front surface 1a of a wafer 1 is followed by a post baking at a temperature ranging from 150 to 300° C. According to an example embodiment, the post baking lasts from 4 to 10 hours. Typically, the product of the post baking temperature (° C.) and the post baking duration (hours) ranges from 1000 to 1800° C.*hours, typically ranging from 1200 to 1600° C.*hours. According to an example embodiment, the post baking is at a temperature of 150° C. and lasts for 10 hours. According to an example embodiment, the post baking is at a temperature of 200° C. and lasts for 8 hours. According to an example embodiment, the post baking is at a temperature of 250° C. and lasts for 6 hours. According to an example embodiment, the post baking is at a temperature of 300° C. and lasts for 4 hours.

The term “plain protective film”, used in the claims, should be interpreted as being a continuous film which is not being patterned, for example, by lithographic procedures. The plain protective film covers at least 90 percent and typically completely the front surface of the wafer.

According to an example embodiment, the plain protective film 2 is kept away from a front surface 1a of the wafer 1 before performing step (a.1) of laminating a plain protective film on a front surface of the wafer. According to an example embodiment, the plain protective film is provided as a roll of the film.

According to an example embodiment, step (a.1) of laminating a plain protective film 2 on a front surface 1a of the wafer 1 is directly followed by step (c) of bonding the provided rigid carrier 3 to the plain protective film 2 by the intermediate of a bonding material layer (not shown in the figures).

According to an example embodiment, the plain protective film 2 comprises a polymer. According to an example embodiment, the plain protective film 2 has a glass transition temperature below 100° C. During lamination, the plain protective film 2 may be rolled on the front surface 1a of the wafer at a temperature at least equal to the glass transition temperature such that the plain protective film 2 becomes more flexible and attach to the front surface 1a of the wafer 1.

According to an example embodiment, the plain protective film 2 comprises 3 layers: a base layer, a core layer, and a cover layer. According to an example embodiment, the base layer comprises a polyester film. The thickness of the base layer range between 15 to 25 μm. According to an example embodiment, the core layer comprises monomer include a compound having one or more α, β-ethylenic unsaturated bonds. According to an example embodiment, the compound has two or more acryloyl groups or methacryloyl group in the molecule. According to an example embodiment, the core layer comprises a binder polymer providing mechanical strength, tenting property and adhesiveness of a photopolymerization composition. According to an example embodiment, the core layer comprises some additives such as dyes, stabilizers, adhesion promoter or thermal polymerization inhibitor. The core layer has the thickness ranging from 15 to 100 μm. According to an example embodiment, the cover layer is a polyolefin film. The cover layer has a thickness ranging from 25 to 30 μm. The base layer is employed as a supporter, while the cover layer serves to prevent a damage of the core layer by dusts and handling thereof. According to an example embodiment, the plain protective film 2 comprises a photosensitive compound. According to an example, the plain protective film 2 comprises a photoresist layer.

According to an example embodiment, the plain protective film 2 has a thickness ranging from 55 to 155 μm.

According to an example embodiment, the plain protective film 2 is glue-free. The glue-free plain protective film 2 beneficially avoids glue contamination on the front surface 1a of the wafer 1. According to an example embodiment, the plain protective film 2 comprises a glue layer having a thickness below 5 nm on the surface of the plain protective film that will contact the front surface 1a of the wafer during step (a.1) of laminating a plain protective film on a front surface of the wafer.

According to an example embodiment, the rigid carrier 3 is transparent such that UV light can be transmitted through it.

According to an example embodiment, the rigid carrier 3 is a glass carrier. According to another example embodiment, the rigid carrier 3 is a semiconductor carrier.

In step (c), the rigid carrier is bounded to the plain protective film by the intermediary of the bonding material layer. According to an example embodiment, the bonding material layer is bounded on the plain protective film, and then, the rigid carrier is bounded on the bonding material layer such that the bonding material is in between the plain protective film and the rigid carrier. According to another example embodiment, the bonding material layer is applied to the rigid carrier, and then, the rigid carrier is bounded on the wafer such that the bonding material is in between the plain protective film and the rigid carrier.

According to an example embodiment, the bonding material layer comprises a glue layer. According to an example embodiment, the glue layer has a thickness ranging between 5 to 200 um.

According to an example embodiment, the bonding material layer comprises at least a layer of photosensitive material, i.e., a photosensitive layer. The photosensitive layer can be a polymer layer. According to an example embodiment, the bonding material layer has a thickness ranging between 20 nm to 200 μm.

According to an example embodiment, the step (e) of separating the rigid carrier 3 and the plain protective film 2 from the wafer 1 comprises a step of mechanical debonding.

According to an example embodiment, the step (e) of separating the rigid carrier 3 and the plain protective film 2 from the wafer 1 comprises a step of exposing the wafer 1 to UV light. The UV exposure will change the chemical properties of the photosensitive bonding material layer to de-bond the rigid carrier 3. According to an example embodiment, the glue layer is wet etched from the plain protective film 2. According to another example embodiment, the glue layer is peeled away from the plain protective film 2.

According to an example embodiment, the step e of separating the rigid carrier 3 and the plain protective film 2 from the wafer 1 comprises two steps:
e.1. separating the rigid carrier 3 from the plain protective film 2; and
e.2. removing the plain protective film 2 from the front surface 1a of the wafer 1.

According to an example embodiment, the step (e.1). separating the rigid carrier 3 from the plain protective film 2 is followed by step (e.2). removing the plain protective film 2 from the front surface 1a of the wafer 1. According to an example embodiment, step (e.1) separates the rigid carrier and at least part of the bonding material layer from the plain protective film.

According to an example embodiment, the step (e.1). of separating the rigid carrier 3 from the plain protective film 2 is directly followed by step (e.2). removing the plain protective film 2 from the front surface 1a of the wafer 1.

The term “wet etching” refers to a material removal process that uses liquid chemicals to remove materials from a wafer. The term is interchangeable with the term “wet stripping” or “wet removing”.

According to an example embodiment, the step e of separating the rigid carrier 3 and the plain protective film 2 from the wafer 1 comprises wet etching the plain protective film 2.

According to an example embodiment, the plain protective film 2 is removed completely with wet etching or wet stripping.

Back processing refers to processing at the surface of the wafer opposed to the surface of the wafer which is bonded to the rigid carrier. The term “backside processing” or “processing the back surface” can be used as alternatives in the same context.

According to an example embodiment, the step (d) of processing a back surface 1b of the wafer 1 comprises a heating step of the back surface 1b above 150° C. According to an example embodiment, the step (d) of processing a back surface 1b of the wafer 1 comprises a heating step of the back surface 1b above 300° C. According to an example embodiment, the step (d) of processing a back surface 1b of the wafer 1 comprises backside thinning, which could be also referred as back-grinding. The backside thinning reduces the thickness of the wafer by removing material from the back surface of the wafer. According to an example embodiment, the step (d) of processing a back surface 1b of the wafer 1 comprises deposition, dry etching, wet etching, plating, and/or cleaning.

In FIG. 2a, wafer 1 is provided. According to an example embodiment, wafer 1 is cleaned with a light acid solution (e.g., 2-3% by volume sulfuric acid solution) followed by a D.I. (Deionized water) water rinse and by a drying with nitrogen gas. The front surface 1a is then substantially free of any kind of organic contamination and metal oxides from previous processes.

In FIG. 2b, the plain protective film 2 is laminated on the front surface 1a of the wafer 1. The temperature and pressure are applied by a hot roll during the lamination process to make the plain protective film 2 more flexible and eliminate any air entrapment between the front surface 1a of the wafer 1 and the plain protective film 2. According to an example embodiment, the roll speed ranges between 0.6 to 1.5 m/min. According to an example embodiment, the wafer 1 is cooled down to room temperature after lamination. According to an example embodiment, a post lamination bake is used to further promote polymer film attachment.

In FIG. 2c, a layer of temporary bonding material (not shown in the figure) is applied on the plain protective film 2. A rigid carrier 3 is bonded to the plain protective film 2 by the intermediate of the adhesive temporary bonding material layer. The temporary bonding material is not in contact with the front surface 1a of the wafer 1. During any steps of the processing, including the post baking of the lamination process or any later heating process, the adhesive temporary bonding material layer does not form any intimate contact with the wafer 1. Therefore, no contamination of the wafer by the temporary bonding material layer occurs during the whole process.

In FIG. 2d, the wafer 1 is flipped over so that the back surface 1b can be easily processed.

In FIG. 2e, the wafer 1 is flipped over again so that the rigid carrier 3 and the plain protective film can be more easily removed from the front surface 1a of the wafer 1.

According to an example embodiment, the wafer 1 comprises a cavity before the step (a.1) of laminating a plain protective film 2 on a front surface 1a of a wafer 1.

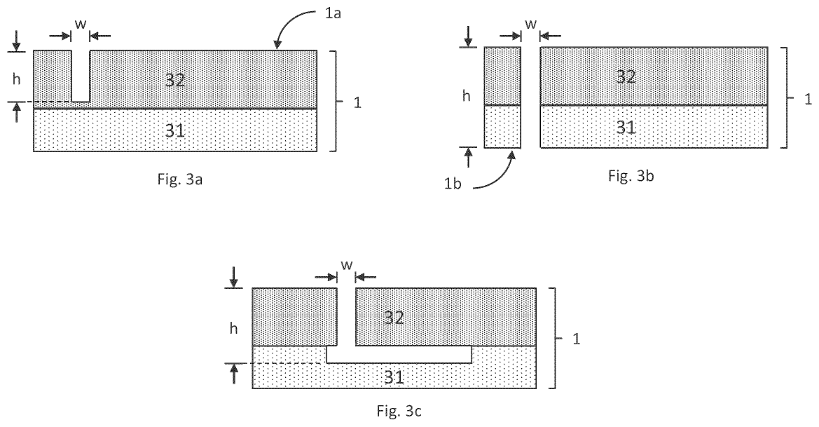

According to an example embodiment, the front surface 1a of the wafer 1 comprises a cavity. According to an example embodiment, as shown in FIG. 3a, the cavity extends vertically from the front surface 1a of the wafer 1. According to an example embodiment, as shown in FIG. 3b, the cavity extends vertically from the front surface 1a to the back surface 1b of the wafer 1. According to an example embodiment, as shown in FIG. 3c, the cavity extends vertically from the front surface 1a of the wafer 1 and fluidically connects with a cavity extending horizontally within the wafer 1.

According to an example embodiment, the cavity has an aspect ratio of at least 1, typically more than 2. The aspect ratio of a cavity is calculated as the longest vertical extent, i.e., the height h, versus the longest horizontal extent, i.e., the width w, measured at the front surface 1a.

AR=h/w

According to an example embodiment, the wafer 1 in the step (a) of providing a wafer 1 for back processing, comprises providing a stack of layers 31, 32, 41, 42, 51, 52.

According to an example embodiment, the wafer 1 in the step (a) of providing a wafer 1 for back processing, comprises providing a stack of layers 31, 32, 41, 42, 51, 52, wherein at least one of the layers is formed by wafer bonding. According to an example embodiment, the wafer bonding is a wafer-to-wafer bonding. Wafer-to-wafer bonding is a process for temporary or permanent joining of two or more sub-wafers with or without an intermediate layer. The wafer 1 provided in the step (a) of providing a wafer (1) for back processing may refer to a wafer already formed by wafer-to-wafer bonding of the sub-wafers. According to an example embodiment, the layers were sub-wafers wherein the sub-wafers are wafers to be bonded together to form a new wafer. According to an example embodiment, the layers 31, 32, 41, 42, 51, 52 or sub-wafers may have been processed before bonding to form wafer 1. According to an example embodiment, a cavity is formed on a surface of the layer 32, 42.

According to an example embodiment, when the contact surface of the two sub-wafers is constituted with substantively same material, one layer can be formed from the wafer-to-wafer bonding.

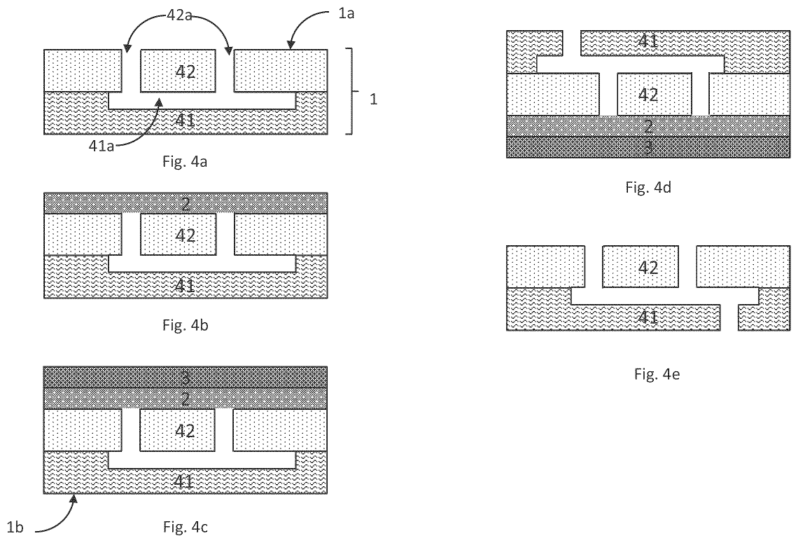

Wafer 1 comprises a stack of layers 41 and 42. The layers 41 and 42 can be different sub-wafers. The wafer 1 can be formed of layer 41 (e.g., a sub-wafer) and 42 (e.g., a different sub-wafer) by wafer bonding before the step (a.1) of laminating a plain protective film 2 on a front surface 1a of a wafer 1. In FIG. 4a, cavity 41a is formed on the layer 41. The cavities 42a are formed on the layer 42 after bonding and extend from the front surface 1a of the wafer 1 to the cavity 41a. According to an example embodiment, the layer 41 and/or 42 can be thinned before bonding.

In FIG. 4b, the plain protective film 2 is laminated on the front surface 1a of the wafer 1. The temperature and pressure applied during the lamination process make the plain protective film 2 more flexible and eliminate any air entrapment between the wafer 1 and the plain protective film 2.

In FIG. 4c, a layer of temporary bonding material (not shown in the figure) is applied on the plain protective film 2. A rigid carrier 3 is bonded to the plain protective film 2 by the intermediate of the adhesive temporary bonding material layer. The temporary bonding material is not contacting the front surface 1a of the wafer 1. During any steps of the processing, including the post baking of the lamination process or any later heating process, the adhesive temporary bonding material layer does not form any intimate contact with the wafer 1. Therefore, no contamination of the wafer by the temporary bonding material layer occurs during the whole process.

In FIG. 4d, the wafer 1 is flipped over so that the back surface 1b can be easily processed. A cavity is formed from the back surface 1b of the wafer 1 and extended to the horizontal cavity 41a. According to an example embodiment, the wafer 41 can be thinned before the cavity is formed.

In FIG. 4e, the wafer 1 is flipped over again so that the rigid carrier 3 and the plain protective film can be more easily removed from the front surface 1a of the wafer 1.

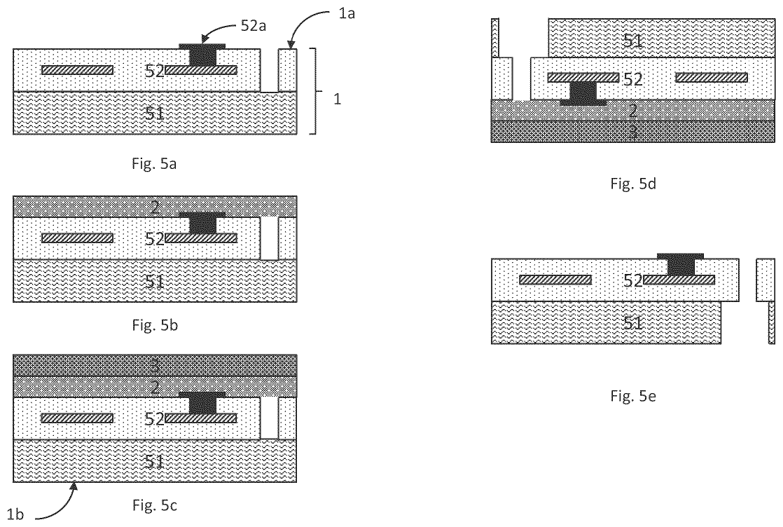

In FIG. 5a, wafer 1 comprises a stack of semiconductor layers 51, 52 wherein at least one semiconductor layer comprises CMOS circuitry embedded therein. Wafer 1 further comprises a protrusion 52a on the front surface 1a. According to an example embodiment, the protrusion is a conductive via for providing electrical connection from the front surface 1a to the embedded CMOS circuitry. According to an example embodiment, the conductive via is a metal via. According to an example embodiment, the front surface 1a may comprise a cavity.

In FIG. 5b, the plain protective film 2 is laminated on the front surface 1a of the wafer 1. The temperature and pressure applied during the lamination process make the plain protective film 2 more flexible and eliminate any air entrapment between the front surface 1a of the wafer 1 and the plain protective film 2. The protrusion 52a has a height exceeding the front surface 1a by less than the thickness of the plain protective film 2.

In FIG. 5c, a layer of temporary bonding material (not shown in the figure) is applied on the plain protective film 2. A rigid carrier 3 is bonded to the plain protective film 2 by the intermediate of the adhesive temporary bonding material layer. The temporary bonding material is not exposed to the front surface 1a of the wafer 1. During any steps of the processing, including the post baking of the lamination process or any later heating process, the adhesive temporary bonding material layer does not form any intimate contact with the wafer 1. Therefore, no contamination of the wafer from the temporary bonding material layer occurs during the whole process.

In FIG. 5d, the wafer 1 is flipped over so that back surface 1b can be easily processed. A cavity is formed from the back surface 1b of the wafer 1. According to an example embodiment, the wafer 51 can be thinned before the cavity is formed. According to an example embodiment, the cavity from the back surface 1b is extended to a cavity from the front surface 1a of the wafer 1.

In FIG. 5e, the wafer 1 is flipped over again so that the rigid carrier 3 and the plain protective film can be more easily removed from the front surface 1a of the wafer 1.

1. A temporary wafer bonding process comprising the steps of:
providing a wafer for back processing by laminating a plain protective film on a front surface of the wafer;
providing a rigid carrier;
bonding the rigid carrier to the plain protective film by an intermediate of a bonding material layer;
processing a back surface of the wafer; and
separating the rigid carrier and the plain protective film from the wafer.

2. The process according to claim 1 wherein the step of separating the rigid carrier and the plain protective film from the wafer comprises:
separating the rigid carrier from the plain protective film; and
followed by removing the plain protective film from the front surface of the wafer.

3. The process according to claim 1, wherein the step of separating the rigid carrier and the plain protective film from the wafer comprises wet etching the plain protective film.

4. The process according to claim 1, wherein the step of processing a back surface of the wafer comprises a heating step of the back surface above 150° C.

5. The process according to claim 1, wherein the wafer is a semiconductor substrate, optionally comprising CMOS circuitry.

6. The process according to claim 1, wherein the rigid carrier is transparent.

7. The process according to claim 1, wherein the rigid carrier is a glass carrier.

8. The process according to claim 1, wherein the front surface of the wafer comprises a cavity, optionally extending to the back surface, before the step of laminating a plain protective film on the front surface of the wafer.

9. The process according to claim 8, wherein the cavity has an aspect ratio of at least 1.

10. The process according to claim 1, wherein the wafer comprises a stack of layers, wherein at least one of the layers is formed by wafer bonding.

11. The process according to claim 1, wherein the plain protective film comprises a polymer having a glass transition temperature below 100° C.

12. The process according to claim 1, wherein the plain protective film either is glue-free or comprises a glue layer thinner than 5 nm on the surface of the plain protective film that will contact the front surface of the wafer during the step of laminating the plain protective film on the front surface of the wafer.

13. The process according to claim 1, wherein the bonding material layer comprises photosensitive material.

14. The process according to claim 13, wherein the step of separating the rigid carrier and the plain protective film from the wafer comprises a step of exposing the wafer to UV light.

15. The process according to claim 13, wherein the step of laminating the plain protective film on the front surface of the wafer is performed at a temperature above 85° C. and a pressure above 103 kPa.
